(19) United States
(12) Patent Application Publication
(10) Pub. No.: US 2020/0152670 A1
(43) Pub. Date: May 14, 2020

(54) ARRAY SUBSTRATE, DISPLAY PANEL AND DISPLAY DEVICE

(71) Applicants: HKC Corporation Limited, Shenzhen (CN); Chongqing HKC Optoelectronics Technology Co., Ltd., Chongqing (CN)

(72) Inventor: Peixin Lin, Shenzhen (CN)

(21) Appl. No.: 16/293,673

(22) Filed: Mar. 6, 2019

Related U.S. Application Data
(63) Continuation of application No. PCT/CN2018/122110, filed on Dec. 19, 2018.

(30) Foreign Application Priority Data
Nov. 8, 2018 (CN) 201821840986.3

(51) Int. Cl. H01L 27/12

(52) U.S. Cl. CPC H01L 27/1255; G02F 1/136213

(57) ABSTRACT

This application discloses an array substrate, a display panel and a display device; a first storage capacitor is formed in a small spacing between a 2nd metal layer and an electrode layer of the array substrate.

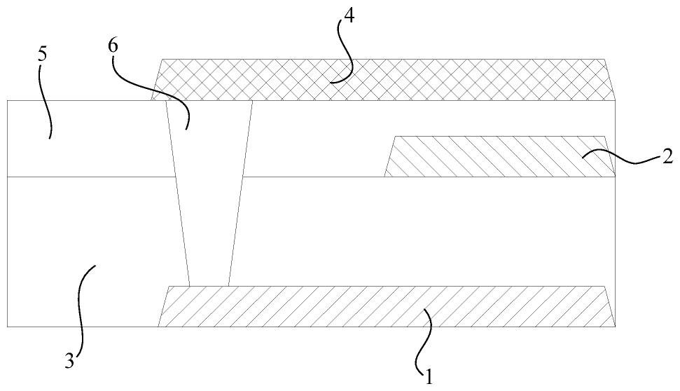

### CROSS REFERENCE TO RELATED APPLICATIONS

The present application is a Continuation Application of PCT Application No. PCT/CN2018/122110 filed on Dec. 19, 2018, which claims the benefit of Chinese Patent Application No. 201821840986.3 filed on Nov. 8, 2018. All the above are hereby incorporated by reference.

### FIELD OF THE DISCLOSURE

This application relates to the field of display device, and particularly, to an array substrate, a display panel and a display device.

### BACKGROUND OF THE DISCLOSURE

The description here only provides the background information on this application, and it does not necessarily constitute the existing technology. According to drive design, the process architecture of display screen can be divided into system on chip (SOC) and gate driver on array (GOA). However, as an important technology of panel design, GOA uses the method of array exposure and development to form gate drive on glass and generate logic circuit to drive gate signal line, i.e., gate drive circuit. Thereby, the introduction of gate driver can be avoided and the cost of liquid crystal display panel can be effectively reduced. Thus, display panels adopting GOA drive are widely used.

It is necessary for GOA circuit to be equipped with storage capacitor so as to maintain the voltage of each pixel zone after the closure of transistor and provide response time for liquid crystal. In existing technology, the storage capacitor is formed from a 1st metal layer which is at the same layer as gate layer, a 2nd metal layer which is at the same layer as source drain layer and a dielectric layer sandwiched between the 1st metal layer and the 2nd metal layer. With the increase of the number of pixels (Pixels Per Inch, abbreviated to PPI) of present liquid crystal display products, the requirement for the capacity of storage capacitor becomes higher. As is known from the formula of storage capacitor ‘Holding C=ε₀εᵣA/d’, the distance d between the 1st metal layer and the 2nd metal layer (i.e., the thickness of dielectric layer) is relatively large so that a relatively large capacity of storage capacitor can be obtained only by increasing the plane area A of the 1st metal layer and the 2nd metal layer as much as possible; however, the excessive plane area occupied by the 1st metal layer and the 2nd metal layer will conflict with the demand for narrow frame of liquid crystal display products.

In conclusion, a proper GOA storage capacitor design has not been found yet in response to high resolution and narrow frame required for liquid crystal display products.

### SUMMARY OF THE DISCLOSURE

It is a main object of the present application to provide an array substrate to realize the demand for narrow frame of GOA display products.

To achieve aforementioned purpose, this application proposes an array substrate comprising a gate drive circuit comprising:

a first metal layer;

a 2nd metal layer located at one side of the 1st metal layer;

a dielectric layer provided between the 1st metal layer and the 2nd metal layer;

an electrode layer electrically connected with the 1st metal layer and located at one side where the 2nd metal layer is far away from the 1st metal layer; and

an insulation layer provided between the electrode layer and the 2nd metal layer; wherein

in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

Optionally, the thickness of the insulation layer is ⅓˜⅗ of that of the dielectric layer.

Optionally, the thickness range of the insulation layer is 1000 μm˜3000 μm.

Optionally, in the direction perpendicular to the surface of the array substrate, the projected area of the electrode layer completely covers that of the 2nd metal layer.

Optionally, in the direction perpendicular to the surface of the array substrate, one end of the projection of the electrode layer is flush with the 2nd metal layer, and the other end is provided to protrude from the 2nd metal layer.

Optionally, in the direction perpendicular to the surface of the array substrate, the projected area of the electrode layer equals to that of the 2nd metal layer.

Optionally, in the direction perpendicular to the surface of the array substrate, the 1st metal layer and the 2nd metal layer are provided in a manner that they partly overlap each other at least to form a 2nd storage capacitor of the gate drive circuit.

Optionally, in the direction perpendicular to the surface of the array substrate, the projected area of the 1st metal layer completely covers that of the 2nd metal layer.

Optionally, in the direction perpendicular to the surface of the array substrate, one end of the projection of the 1st metal layer is flush with the 2nd metal layer, and the other end is provided to protrude from the 2nd metal layer.

Optionally, in the direction perpendicular to the surface of the array substrate, the projected area of the 1st metal layer equals to that of the 2nd metal layer.

Optionally, the insulation layer and the dielectric layer are provided with conductive through-hole spaced apart from the 2nd metal layer, and the electrode layer is electrically connected with the 1st metal layer via the conductive through-hole.

Optionally, the insulation layer is made from silica gel.

Optionally, the 1st metal layer and the gate layer of the gate drive circuit are formed synchronously, and the 2nd metal layer and a source drain layer comprising a source and a drain are formed synchronously.

This application also provides a display panel comprising an array substrate comprising a gate drive circuit comprising:

a 1st metal layer;

a 2nd metal layer;

a dielectric layer provided between the 1st metal layer and the 2nd metal layer;

an electrode layer electrically connected with the 1st metal layer and located at one side where the 2nd metal layer is far away from the 1st metal layer; and

an insulation layer provided between the electrode layer and the 2nd metal layer; wherein

in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

This application also provides a display device comprising a display panel comprising an array substrate comprising a gate drive circuit comprising:

a 1st metal layer;

a 2nd metal layer;

a dielectric layer provided between the 1st metal layer and the 2nd metal layer;

an electrode layer electrically connected with the 1st metal layer and located at one side where the 2nd metal layer is far away from the 1st metal layer; and

an insulation layer provided between the electrode layer and the 2nd metal layer; wherein

in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

Optionally, the thickness range of the insulation layer is 1000 μm˜3000 μm.

Optionally, in the direction perpendicular to the surface of the array substrate, the projected area of the electrode layer completely covers that of the 2nd metal layer.

Optionally, in the direction perpendicular to the surface of the array substrate, the 1st metal layer and the 2nd metal layer are provided in a manner that they partly overlap each other at least to form a 2nd storage capacitor of the gate drive circuit.

Optionally, the insulation layer and the dielectric layer are provided with conductive through-hole spaced apart from the 2nd metal layer, and the electrode layer is electrically connected with the 1st metal layer via the conductive through-hole.

In the technical solution of this application, an electrode layer is disposed at one side where a 2nd metal layer is far away from a 1st metal layer, and an insulation layer (its thickness is smaller than that of dielectric layer) is disposed at the 2nd metal layer and the electrode layer; the electrode layer is disposed in a manner that it is electrically connected with the 1st metal layer and at least partly overlaps with the 2nd metal layer; thereby, a 1st storage capacitor of gate drive circuit is formed between the electrode layer and the 2nd metal layer; compared with the way of using the 1st metal layer and the 2nd metal layer to form storage capacitor in exemplary technology, the thickness of the insulation layer in this embodiment is smaller than that of the dielectric layer between the 1st metal layer and the 2nd metal layer, thus helping to increase the capacitance of the storage capacitor; In other words, when equivalent capacitance is kept, the plane area of the storage capacitor of this embodiment is smaller, thus reducing the plane area outside display zone of liquid crystal display device occupied by storage capacitor and helping to realize narrow frame of liquid crystal display device.

### BRIEF DESCRIPTION OF THE DRAWINGS

To describe the technical solution in the embodiments of this application or existing technology more clearly, a brief introduction will be made on the drawings to be used in the description of embodiments or existing technology. Obviously, the drawings in the description below are only some embodiments of this application, and ordinary artisans concerned can obtain other drawings on the basis of the structure shown by these drawings without creative efforts.

The sole FIGURE is a schematic sectional view of an embodiment of the array substrate of this application.

Labels illustration for drawings

| Label | Name | Label | Name |
|---|---|---|---|
| 1 | 1st metal layer | 2 | 2nd metal layer |
| 3 | dielectric layer | 4 | electrode layer |
| 5 | insulation layer | 6 | conductive |
| | | | through-hole |

The object realization, function characteristics and advantages of this application will be further described with reference to embodiments and drawings.

### DETAILED DESCRIPTION OF THE EMBODIMENTS

The technical solutions in the embodiments of the present application will be clearly and completely described hereafter in reference to the drawings in the embodiments of the present application. It is apparent that the described embodiments are merely a part of embodiments rather than all the embodiments of the present application. All the other embodiments obtained by the artisans concerned on the basis of the embodiments in the present application without creative efforts fall within the scope of claims of the present application.

It is to be understood that, all of the directional instructions in the exemplary embodiments of the present disclosure (such as top, down, left, right, front, back) can only be used for explaining relative position relations, moving condition of the elements under a special form (referring to the FIGURE), and so on, if the special form changes, the directional instructions changes accordingly.

In addition, the descriptions, such as the “first”, the “second” in the present application, are only used for descriptive purpose, and cannot be understood as indicating or suggesting relative importance or impliedly indicating the number of the indicated technical features. Therefore, the character indicated by the “first”, the “second” can explicitly or implicitly include at least one feature. Additionally, the technical solution of each embodiment can be combined with each other on the condition that it can be realized by ordinary artisans concerned; if the combination of technical solution contradicts each other or cannot be realized, it should be regarded that the combination of such solution does not exist, nor is it in the protection scope required by the present application.

This application proposes an array substrate for liquid crystal display panel, and it can be understood that the liquid crystal display panel comprises a color film substrate and an array substrate which are spaced apart and face each other as well as liquid crystal filled between the two substrates; the liquid crystal is located inside a liquid crystal box formed by laminating the array substrate and the color film substrate. Having general applicability, the liquid crystal display panel can be used for liquid crystal television, liquid crystal display etc., and the present design is not limited to such usage.

As is known to all, an array substrate comprises a plurality of data lines disposed longitudinally, a plurality of scanning lines disposed transversely, and a plurality of pixel zones defined by scanning lines and data lines; wherein each pixel zone connects and corresponds to a data line and a scanning line, and each scanning line is connected to a gate drive circuit to supply scanning voltage to each pixel zone, and each data line is connected to source drive circuit to supply grey-scale voltage to each pixel zone. Usually, the gate drive circuit comprises a TFT, a storage capacitor and a liquid crystal capacitor formed from a pixel electrode located at pixel zone, a common electrode at one side of color film substrate, and liquid crystal between the two.

According to the principle of liquid crystal display panel GOA driving, a scanning voltage is inputted via a scanning line, and the TFT at the same row will be opened simultaneously, then the TFT at the next row will be opened simultaneously in a certain time, and so on. The open time of TFT at each row is relatively short, so the time of liquid crystal capacitor charge and liquid crystal deflection control is relatively short, making it difficult to reach the response time of liquid crystal. By means of storage capacitor, the voltage of each pixel zone can be maintained after the closure of TFT, thus providing time for liquid crystal response.

In exemplary technology, a storage capacitor is formed along with a 1st metal layer at the same layer as gate layer, a 2nd metal layer at the same layer as source drain layer, and a dielectric layer sandwiched between the 1st metal layer and the 2nd metal layer; as is known from the formula of storage capacitor Holding C=ε₀εᵣA/d, the capacitance of storage capacitor is in proportion to the plane area of 1st metal layer and 2nd metal layer and is in inverse proportion to the thickness between 1st metal layer and 2nd metal layer; however, the thickness of dielectric layer is relatively large, so in order to ensure the capacitance of storage capacitor can still be kept at a relatively high value, there is no way but to increase the plane area of 1st metal layer and 2nd metal layer as much as possible; however, such setting will undoubtedly increase the area on both sides of the display zone of liquid crystal display device, which conflicts with the demand for narrow frame of liquid crystal display device. Therefore, the present application has made related improvement on array substrate:

In the embodiment of this application, with reference to the FIGURE, the gate drive circuit of array substrate comprises:

a 1st metal layer 1;

a 2nd metal layer 2 located at one side of the 1st metal layer;

a dielectric layer 3 provided between the 1st metal layer 1 and the 2nd metal layer 2;

an electrode layer 4 electrically connected with the 1st metal layer 1 and located at one side where the 2nd metal layer 2 is far away from the 1st metal layer 1; and

an insulation layer 5 provided between the electrode layer 4 and the 2nd metal layer 2;

wherein

in the direction perpendicular to the surface of the array substrate, the electrode layer 4 and the 2nd metal layer 2 are provided in a manner that they partly overlap each other at least to form a 1st storage capacitor of the gate drive circuit; the thickness of the insulation layer 5 is smaller than that of the dielectric layer 3.

In this embodiment, the 1st metal layer 1 and the gate layer of gate drive circuit are formed synchronously, and the 2nd metal layer 2 and the source drain layer comprising a source and a drain are formed synchronously, and the dielectric layer 3 and a passivation layer between the gate layer and the source drain layer, thus facilitating the processing and forming of array substrate, helping to improve the processing efficiency of array substrate, and reducing processing cost.

Besides, in this embodiment, the 1st metal layer 1 is at the lower side of the 2nd metal layer 2 to form a bottom gate TFT structure; it can be understood that the bottom gate TFT structure is the one widely used in existing technology, having the advantages of stable structure, simple design etc.; Undoubtedly, in other embodiments, the 1st metal layer may also be at the upper side of the 2nd metal layer to form a top gate TFT structure, and the present design is not limited to this.

Based on the bottom gate TFT structure, an electrode layer 4 is additionally disposed at the upper side of the 2nd metal layer 2, and an insulation layer 5 (its thickness is smaller than dielectric layer 3) is disposed between the electrode layer 4 and the 2nd metal layer 2; the electrode layer 4 is electrically connected with the 1st metal layer 1, and the electrode layer 4 and the 2nd metal layer 2 at least partly overlap each other to form a 1st storage capacitor between the electrode layer 4 and the 2nd metal layer 2. In this embodiment, the εᵣ of insulation layer 5 and dielectric layer 3 are basically the same (both are 7 or so), and the thickness of insulation layer 5 is smaller than that of dielectric layer 3; as is known from Holding C=ε₀εᵣA/d, when the polar plate plane area of the 1st storage capacitor is consistent with that of the former storage capacitor, the capacitance of the 1st storage capacitor will be larger than that of the former storage capacitor; in other words, when the capacitance of 1st storage capacitor is the same as that of the former storage capacitor, the plane area of 1st storage capacitor polar plate (the electrode layer 4 and the 2nd metal layer 2) is smaller than that of former storage capacitor polar plate, thus helping to reduce the liquid crystal display plane occupied by storage capacitor and realizing the design of narrow frame of liquid crystal display device. In this embodiment, the insulation layer 5 and the dielectric layer 3 are provided with conductive through-hole spaced apart from the 2nd metal layer 2, and the electrode layer 4 is electrically connected with the 1st metal layer 1 via the conductive through-hole 6; it can be understood that conductive through-hole 6 is opened on the array substrate to realize the conduction of different layers, which is the conventional method in this field and has the advantages of simple process, stable conduction, etc.; Undoubtedly, in other embodiment, the electrode layer 4 and the 1st metal layer 1 may also be electrically connected in other ways, and the present design is not limited to this.

In the technical solution of this application, an electrode layer 4 is disposed at one side where the 2nd metal layer 2 is far away from the 1st metal layer 1, and an insulation layer 5 (its thickness is smaller than dielectric layer 3) is disposed at the 2nd metal layer 2 and the electrode layer 4, and the electrode layer 4 is electrically connected with the 1st metal layer 1 and at least partly overlaps with the 2nd metal layer 2, and thereby, a 1st storage capacitor of gate drive circuit is formed between the electrode layer 4 and the 2nd metal layer 2; compared with the method of using the 1st metal layer and the 2nd metal layer to form storage capacitor in exemplary technology, in this embodiment, the thickness of insulation layer 5 is smaller than that of the dielectric layer 3 between the 1st metal layer 1 and the 2nd metal layer 2 so as to help to increase the capacitance of storage capacitor; in other words, when the same capacitance is kept, the plane area of the storage capacitor of this embodiment is smaller, thus reducing the plane area outside the display zone of liquid crystal display device occupied by storage capacitor, and helping to realize the narrow frame of liquid crystal display device.

Optionally, the thickness of insulation layer 5 is ⅓˜⅗ of the dielectric layer 3; it can be understood that the thickness of insulation layer 5 is within a proper range in relation to the dielectric layer 3, and thereby the capacity of storage capacitor can be increased, the excessive plane area of storage capacitor can be avoided, and the excessive difficulty of array substrate processing caused by the excessive process difficulty of array substrate can be prevented. It is to be noted that the present design is not limited to this and in other embodiments the thickness of insulation layer 5 may also be other proportion that the dielectric layer 3 is smaller than 1. Particularly, in this embodiment, the thickness range of insulation layer 5 is 1000 μm˜3000 μm; on one hand, a relatively large capacitance can be ensured for storage capacitor; on the other hand, the occurrence of conduction between the 2nd metal layer 2 and the electrode layer 4 can be avoided. Having general applicability, the insulation layer 5 is made from silica gel, and it can be understood that silica gel is an insulation material widely used in existing technology and has the advantages of easy availability and low price etc.; it should be noted that the present design is not limited to this and the insulation layer 5 may be made from other materials such as plastics etc. in other embodiments.

In this embodiment, with reference to the FIGURE, in the direction perpendicular to the surface of array substrate, the projected area of electrode layer 4 completely covers that of the 2nd metal layer. It can be understood that in the formula ‘Holding C=ε₀εᵣA/d’, A represents the area that the two polar plates face. Therefore, to avoid the waste of the plane area of the 2nd metal layer 2, the projected area of the 2nd metal layer 2 along vertical direction completely falls in the projected area of the electrode layer 4, i.e., all of the plane area of the 2nd metal layer 2 will be regarded as the area that the polar plates face. Additionally, in this embodiment, one end of the electrode layer 4 is to be connected with the conductive through-hole 6, so the plane area of electrode layer 4 is set to be larger than the 2nd metal layer 2, and the conductive through-hole 6 is at the front side of the 2nd metal layer 2, and the front side of electrode layer 4 also protrudes from the 2nd metal layer 2; undoubtedly, in other embodiments, to avoid the waste of the plane area of electrode layer 4, the projected area of electrode layer 4 along vertical direction also completely falls in the projected area of the 2nd metal layer 2, i.e., the electrode layer 4 and the 2nd metal layer 2 are disposed in a manner that they completely overlap each other in vertical direction. It is to be understood that the present design is not limited to this, and in other embodiments, the projection of the 2nd metal layer 2 and the electrode layer 4 along vertical direction may also partly overlap each other.

The concept of this application lies in that a 2nd metal layer 2, an electrode layer 4 and an insulation layer 5 are used to form a storage capacitor with smaller spacing between polar plates; thus when the same capacitance is satisfied, the plane area of storage capacitor will be reduced; it can be understood that whether the storage capacitor exists between the 1st metal layer and the 2nd metal layer or not, they both fall within the protection scope of this application. In this embodiment, to further increase the capacitance of the storage capacitor of gate drive circuit, in the direction perpendicular to the surface of array substrate, the 1st metal layer 1 at least partly overlaps with the 2nd metal layer 2 so as to form the 2nd storage capacitor of gate drive circuit; it can be understood that the 2nd storage capacitor and the 1st storage capacitor are disposed in parallel, and the total capacitance after series connection must be larger than the 1st storage capacitor. Thus, the capacitance of the storage capacitor of gate drive circuit has been improved in a better effect. Besides, in this embodiment, one end of the 1st metal layer 1 is to be connected with the conductive through-hole 6, so the plane area of 1st metal layer 1 is set to be larger than the 2nd metal layer 2, and the conductive through-hole 6 is at the front side of the 2nd metal layer 2, and the front side of the 1st metal layer 1 also protrudes from the 2nd metal layer 2; undoubtedly, in other embodiments, to avoid the waste of the plane area of the 1st metal layer 1, the projected area of the 1st metal layer 1 along vertical direction also completely falls in the projected area of the 2nd metal layer 2, i.e., the 1st metal layer 1 and the 2nd metal layer 2 are disposed in a manner that they completely overlap each other in vertical direction. It is to be understood that the present design is not limited to this, and in other embodiments, the projection of the 1st metal layer 1 and the electrode layer 4 along vertical direction may also partly overlap each other.

This application also proposes a display device comprising a display panel comprising an array substrate, and the concrete structure of the array substrate refers to the embodiment above; the display device adopts all the technical solutions of all the embodiments above, so it at least has all the beneficial effects of the technical solution of the embodiments above, and its description will not be repeated here.

The description above is only an optional embodiment of this application rather than a limitation on the protection scope of this application, and any equivalent structural changes made in reference to the description and drawings of this application under the concept of this application or its direct/indirect application to other related fields are all included in the protection scope of this application.

What is claimed is:

1. An array substrate which comprises a gate drive circuit comprising:
a first metal layer;
a 2nd metal layer located at one side of the 1st metal layer;
a dielectric layer provided between the 1st metal layer and the 2nd metal layer;
an electrode layer electrically connected with the 1st metal layer and located at one side where the 2nd metal layer is far away from the 1st metal layer; and
an insulation layer provided between the electrode layer and the 2nd metal layer; wherein
in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

2. The array substrate according to claim 1, wherein the thickness of the insulation layer is ⅓˜⅗ of that of the dielectric layer.

3. The array substrate according to claim 2, wherein the thickness range of the insulation layer is 1000 μm˜3000 μm.

4. The array substrate according to claim 1, wherein in the direction perpendicular to the surface of the array substrate, the projected area of the electrode layer completely covers that of the 2nd metal layer.

5. The array substrate according to claim 4, wherein in the direction perpendicular to the surface of the array substrate, one end of the projection of the electrode layer is flush with the 2nd metal layer, and the other end is provided to protrude from the 2nd metal layer.

6. The array substrate according to claim 4, wherein in the direction perpendicular to the surface of the array substrate, the projected area of the electrode layer equals to that of the 2nd metal layer.

7. The array substrate according to claim 1, wherein in the direction perpendicular to the surface of the array substrate, the 1st metal layer and the 2nd metal layer are provided in a manner that they partly overlap each other at least to form a 2nd storage capacitor of the gate drive circuit.

8. The array substrate according to claim 6, wherein in the direction perpendicular to the surface of the array substrate, the projected area of the 1st metal layer completely covers that of the 2nd metal layer.

9. The array substrate according to claim 8, wherein in the direction perpendicular to the surface of the array substrate, one end of the projection of the 1st metal layer is flush with the 2nd metal layer, and the other end is provided to protrude from the 2nd metal layer.

10. The array substrate according to claim 8, wherein in the direction perpendicular to the surface of the array substrate, the projected area of the 1st metal layer equals to that of the 2nd metal layer.

11. The array substrate according to claim 1, wherein the insulation layer and the dielectric layer are provided with conductive through-hole spaced apart from the 2nd metal layer, and the electrode layer is electrically connected with the 1st metal layer via the conductive through-hole.

12. The array substrate according to claim 1, wherein the insulation layer is made from silica gel.

13. The array substrate according to claim 1, wherein the 1st metal layer and the gate layer of the gate drive circuit are formed synchronously, and the 2nd metal layer and a source drain layer comprising a source and a drain are formed synchronously.

14. A display panel comprising an array substrate comprising a gate drive circuit comprising:
a first metal layer;
a 2nd metal layer located at one side of the 1st metal layer;
a dielectric layer provided between the 1st metal layer and the 2nd metal layer;
an electrode layer electrically connected with the 1st metal layer and located at one side where the 2nd metal layer is far away from the 1st metal layer; and
an insulation layer provided between the electrode layer and the 2nd metal layer; wherein
in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

15. A display device comprising a display panel comprising an array substrate comprising a gate drive circuit comprising:
a first metal layer;
a 2nd metal layer located at one side of the 1st metal layer;
a dielectric layer provided between the 1st metal layer and the 2nd metal layer;
an electrode layer electrically connected with the 1st metal layer and located at one side where the 2nd metal layer is far away from the 1st metal layer; and
an insulation layer provided between the electrode layer and the 2nd metal layer; wherein
in the direction perpendicular to the surface of the array substrate, the electrode layer and the 2nd metal layer are provided in a manner that they partly overlap each other at least to form a 1st storage capacitor of the gate drive circuit; the thickness of the insulation layer is smaller than that of the dielectric layer.

16. The display device according to claim 15, wherein the thickness of the insulation layer is ⅓˜⅗ of that of the dielectric layer.

17. The display device according to claim 16, wherein the thickness range of the insulation layer is 1000 μm˜3000 μm.

18. The display device according to claim 15, wherein in the direction perpendicular to the surface of the array substrate, the projected area of the electrode layer completely covers that of the 2nd metal layer.

19. The display device according to claim 15, wherein in the direction perpendicular to the surface of the array substrate, the 1st metal layer and the 2nd metal layer are provided in a manner that they partly overlap each other at least to form a 2nd storage capacitor of the gate drive circuit.

20. The display device according to claim 15, wherein the insulation layer and the dielectric layer are provided with conductive through-hole spaced apart from the 2nd metal layer, and the electrode layer is electrically connected with the 1st metal layer via the conductive through-hole.
